(19) United States
(12) Patent Application Publication
(10) Pub. No.: US 2022/0252907 A1
(43) Pub. Date: Aug. 11, 2022

(54) OPTICAL ALIGNMENT SYSTEMS AND METHODS USING SILICON DIODES

(71) Applicant: Alpine Optoelectronics, Inc., Fremont, CA (US)

(72) Inventors: Dawei Zheng, Fremont, CA (US); Xingyu Zhang, Fremont, CA (US); Tongqing Wang, Fremont, CA (US)

(21) Appl. No.: 17/172,525

(22) Filed: Feb. 10, 2021

(51) Int. Cl. G02F 1/01; H01S 5/00; H01S 5/02251; H01S 5/02253; H01S 5/40; H01L 27/144

(52) U.S. Cl. CPC G02F 1/0123; H01S 5/0085; H01S 5/02251; G02F 2203/48; H01S 5/0071; H01S 5/4087; H01L 27/1443; H01S 5/02253

(57) ABSTRACT

An integrated photonics chip comprising: a plurality of optical channels extending a length of the integrated photonics chip; at least one variable optical attenuator (VOA) being optically connected to one of the plurality of optical channels, the at least one VOA comprising a silicon diode; at least one modulator being optically connected to another of the plurality of optical channels, the at least one modulator comprising a silicon diode; wherein the silicon diodes of the at least one VOA and the at least one modulator are adapted to receive biasing voltages; and wherein an application of the biasing voltages causes the silicon diodes of the at least one VOA and the at least one modulator to be reverse-biased, such that the at least one VOA and the at least one modulator are each adapted to detect a photocurrent of an optical signal being propagated along the plurality of optical channels.

### BACKGROUND OF INVENTION

### 1. Field of the Invention

The invention relates generally to systems and methods of optically aligning lasers to integrated photonics chips, and more specifically to systems and methods of optically aligning lasers to integrated photonics chips using reverse-biased silicon diodes.

### 2. Description of the Related Art

Over the last twenty years or so, silicon photonics technology has gained significant progress in the field of integrated photonics, making silicon photonics a competitive technology platform for the most modern and state-of-the-art optical communication applications. In optical communications, for example, an optical transmitter and optical receiver pair is needed (at minimum) to optically transmit and receive information and data signals (in the form of light signals, for example). To achieve a high data rate, and over a distance longer than 100 meters (m), an optical transmitter would conventionally include at least a continuous wave or tunable laser source and an external modulator. The external modulator, with specific regard to the silicon photonics technology platform, may conventionally be silicon-based and may thus comprise an electrical diode disposed within a waveguide, for example. The electrical diode may typically be formed by implanting P and N-type dopants into the silicon waveguide. As an example, the silicon diode can be based on either a P-N junction or a P-I-N junction, similar to those shown in FIGS. 1A-1B, respectively. As is known, the working principle of P-N junction-based modulators is carrier depletion, while the working principle of P-I-N junction-based modulators is carrier injection. As another example, depending on the optical application, the P-I-N junction-based silicon diode can be implemented as a variable optical attenuator (VOA). The VOA is an optical component often used in silicon integrated photonics chips as a means for optical power attenuation and/or channel shutoff, for example.

As mentioned above, the optical transmitter may conventionally further comprise a continuous wave or tunable laser source, as an example. The laser source (e.g., a laser chip) must be optically aligned to the input of the integrated photonics chip/die (e.g., silicon modulator chip) to achieve desired transmitter functionality. The laser alignment can be realized through multiple approaches, such as, for example, using a lens system, directly attaching the laser chip to the input of the silicon modulator chip, or using a fiber/fiber array to connect the laser source to the input of the silicon modulator chip. During this laser alignment process, either the laser chip, or the lens/fiber array, or both need to be moved and physically adjusted to achieve the desired/preferred optical coupling results, that is, to allow a maximal amount of laser light to be coupled into the silicon modulator chip, for example. In order to best guide the lens (or fiber) system and/or laser chip movement/adjustment, the amount of laser light being launched into the silicon modulator chip needs to be measured and monitored.

Conventionally, to complete such a monitoring task, an on-chip photodetector (PD) can be optically connected to the silicon modulator chip bus waveguide, where the on-chip PD is adapted to detect the incoming laser light, such that the resultant photocurrent can be read electrically, as shown in FIG. 4, for example. Typically, the on-chip PD may be optically connected to the bus waveguide via an optical tap (e.g., a tap coupler) disposed before or after the external modulator. Configured with a high tap ratio, the optical tap takes a relatively small portion of the incoming laser light (e.g., 0.5 to 5%) and sends the light portion to the on-chip PD, as an example. The measured photocurrent reading may thus provide user-feedback regarding the position and angle of incidence of the laser beam relative to the integrated photonics chip, for example. In the particular case of a silicon-based optical transmitter, the on-chip PD is typically constructed from a silicon-germanium (SiGe) alloy, which can detect light in the communication wavelength region of 1260 to 1625 nanometers (nm), for example.

While SiGe-based photodetectors may be monolithically integrated on silicon modulator chips and possess cost and performance advantages over hybrid photodiodes used on other competing technology platforms, the SiGe photodetectors have a low electrostatic discharge (ESD) voltage rating. As such, pressure and expectation falls on the packaging house handling the silicon modulator chip having the integrated SiGe photodetectors to properly and carefully package, ship, and otherwise distribute the silicon modulator chip. As a result, the yield of the SiGe PD may be easily and thus negatively impacted by the improper handling of the silicon modulator chip, due to the high levels of ESD sensitivity of the SiGe photodetectors. Moreover, the epitaxial growth of SiGe requires a specific yield. In the case of multi-channel integrated silicon photonics devices (e.g., DR4 or DR8 transceiver chips), the increased total number of SiGe photodetectors (one disposed on each channel, for example) used on the devices will compromise the yield. In addition, the optical tap coupler, mentioned above, used to optically connect the SiGe PD to the bus waveguide on the silicon modulator chip may behave as a dispersive media across the communication wavelengths. Specifically, the high tap ratio of the tap coupler, intended to limit the loss of the main optical channel, gives rise to severe chromatic dispersion for the propagating laser light. Therefore, the tap coupler and SiGe PD pair renders the silicon modulator chip ill-suited for wide broadband operation and sensitive to process variations.

Therefore, there is a need to solve the problems described above by providing a system and method for efficiently, cost-effectively, and easily optically aligning laser sources to integrated photonics chips using reverse-biased silicon diodes.

The aspects or the problems and the associated solutions presented in this section could be or could have been pursued; they are not necessarily approaches that have been previously conceived or pursued. Therefore, unless otherwise indicated, it should not be assumed that any of the approaches presented in this section qualify as prior art merely by virtue of their presence in this section of the application.

### BRIEF INVENTION SUMMARY

This Summary is provided to introduce a selection of concepts in a simplified form that are further described below in the Detailed Description. This Summary is not intended to identify key aspects or essential aspects of the claimed subject matter. Moreover, this Summary is not intended for use as an aid in determining the scope of the claimed subject matter.

In an aspect, an integrated photonics chip is provided. The integrated photonics chip may comprise: a plurality of optical channels extending a length of the integrated photonics chip; at least one variable optical attenuator (VOA) being optically connected to one of the plurality of optical channels, the at least one VOA comprising a silicon diode; at least one modulator being optically connected to another of the plurality of optical channels, the at least one modulator comprising a silicon diode; wherein the silicon diodes of the at least one VOA and the at least one modulator are adapted to receive biasing voltages; and wherein an application of the biasing voltages causes the silicon diodes of the at least one VOA and the at least one modulator to be reverse-biased, such that the at least one VOA is adapted to detect a photocurrent of a first optical signal being propagated along the one of the plurality of optical channels, and the at least one modulator is adapted to detect a photocurrent of a second optical signal being propagated along the another of the plurality of optical channels. Thus, an advantage of using silicon-based modulators and VOAs is that the use of additional on-chip tap couplers bundled with photodiodes may be negated, which simplifies the design of the disclosed silicon photonics chip, and thus reduces manufacturing costs. Another advantage is that, because the use of additional on-chip tap couplers bundled with photodiodes may be negated, the overall size of the integrated photonics chip may be miniaturized, further reducing manufacturing costs. An additional advantage is that, because no electrical power is needed for operating the negated on-chip photodiodes, the operational costs associated with operating the disclosed integrated photonics chip may be reduced. Another advantage is that, because no tap couplers are used, the wavelength dispersion of the propagating laser light may be improved. Another advantage is that, because no SiGe photodiodes are used, the typical issues of high ESD sensitivity and specificity of the SiGe epitaxial growth yield may be avoided.

In another aspect, a method of optically aligning a laser light source to an integrated photonics chip is provided, the integrated photonics chip comprising a first and a second optical channels, and a first and a second variable optical attenuators (VOAs) being optically connected to the first and the second optical channels, respectively, the first and the second VOAs each having a silicon diode, wherein the silicon diodes of the first VOA and the second VOA are each adapted to receive a first and a second biasing voltages, respectively. The method may comprise the steps of: positioning the laser source to face a first end of the integrated photonics chip, such that an optical signal being launched by the laser source can enter the integrated photonics chip at the first end; applying the first and the second biasing voltages to each of the silicon diodes of the first and the second VOAs, the first and the second biasing voltages causing the silicon diodes to become reverse-biased, such that a photocurrent of a propagating optical signal can be detected by each of the first and the second VOAs; operating the laser source, such that a first and a second optical signals are launched into the first and the second optical channels, respectively, at the first end; and measuring an optical power of each of the first and the second optical signals by detecting the photocurrent of each of the first and the second optical signals, respectively, using the reverse-biased first and second VOAs, such that to monitor and thus selectively adjust a position of the laser source and an angle of incidence of each of the first and the second optical signals for optically aligning the laser source to the integrated photonics chip. Thus, an advantage is that the required number of on-chip optical components is simplified and thus reduced, increasing chip optimization and circuit miniaturization. An additional advantage of the disclosed optical alignment method using reverse-biased VOAs and modulators is that a laser source may be efficiently and cost-effectively aligned to an integrated photonics die. Another advantage of the disclosed optical alignment method is that a laser source may be aligned to an integrated photonics die using existing, on-chip optical components, thus reducing operational costs.

In another aspect, a method of optically aligning a laser light source to an integrated photonics chip is provided, the integrated photonics chip comprising a first and a second optical channels, and a first and a second modulators being optically connected to the first and the second optical channels, respectively, the first and the second modulators each having a silicon diode, wherein the silicon diodes of the first and the second modulators are each adapted to receive a first and a second biasing voltages, respectively. The method may comprise the steps of: positioning the laser source to face a first end of the integrated photonics chip, such that an optical signal being launched by the laser source can enter the integrated photonics chip at the first end; applying the first and the second biasing voltages to each of the silicon diodes of the first and the second modulators, respectively, the first and the second biasing voltages causing the silicon diodes to become reverse-biased, such that a photocurrent of a propagating optical signal can be detected by each of the first and the second modulators; operating the laser source, such that a first and a second optical signals are launched into the first and the second optical channels, respectively, at the first end; and measuring an optical power of each of the first and the second optical signals by detecting a photocurrent of each of the first and the second optical signals, respectively, using the reverse-biased first and second modulators, such that to monitor and thus selectively adjust a position of the laser source and an angle of incidence of each of the first and the second optical signals for optically aligning the laser source to the integrated photonics chip. Thus, an advantage is that the required number of on-chip optical components is simplified and thus reduced, increasing chip optimization and circuit miniaturization. An additional advantage of the disclosed optical alignment method using reverse-biased VOAs and modulators is that a laser source may be efficiently and cost-effectively aligned to an integrated photonics die. Another advantage of the disclosed optical alignment method is that a laser source may be aligned to an integrated photonics die using existing, on-chip optical components, thus reducing operational costs.

The above aspects or examples and advantages, as well as other aspects or examples and advantages, will become apparent from the ensuing description and accompanying drawings.

### BRIEF DESCRIPTION OF THE DRAWINGS

For exemplification purposes, and not for limitation purposes, aspects, embodiments or examples of the invention are illustrated in the figures of the accompanying drawings, in which:

FIGS. 1A-1B are diagrams illustrating exemplary perspective views of a P-N junction and a P-I-N junction, respectively, integrated on a silicon photonics chip, according to an aspect.

FIG. 2 is a diagram illustrating a top view of a multi-channel integrated silicon photonics chip, according to several aspects.

FIGS. 3A-3C are diagrams illustrating top views of methods of optically aligning a laser light source to the multi-channel integrated silicon photonics chip of FIG. 2, according to several aspects.

FIG. 4 is an exemplary plot illustrating the photocurrent measured via the prior art approach of using a SiGe photodiode, according to an aspect.

FIG. 5 is an exemplary plot illustrating the photocurrent measured via a modulator as a function of laser light source power, according to an aspect.

FIG. 6 is an exemplary plot illustrating the photocurrent measured via a VOA as a function of laser light source power, according to an aspect.

### DETAILED DESCRIPTION

What follows is a description of various aspects, embodiments and/or examples in which the invention may be practiced. Reference will be made to the attached drawings, and the information included in the drawings is part of this detailed description. The aspects, embodiments and/or examples described herein are presented for exemplification purposes, and not for limitation purposes. It should be understood that structural and/or logical modifications could be made by someone of ordinary skills in the art without departing from the scope of the invention. Therefore, the scope of the invention is defined by the accompanying claims and their equivalents.

It should be understood that, for clarity of the drawings and of the specification, some or all details about some structural components or steps that are known in the art are not shown or described if they are not necessary for the invention to be understood by one of ordinary skills in the art.

For the following description, it can be assumed that most correspondingly labeled elements across the figures (e.g., 210 and 310, etc.) possess the same characteristics and are subject to the same structure and function. If there is a difference between correspondingly labeled elements that is not pointed out, and this difference results in a non-corresponding structure or function of an element for a particular embodiment, example or aspect, then the conflicting description given for that particular embodiment, example or aspect shall govern.

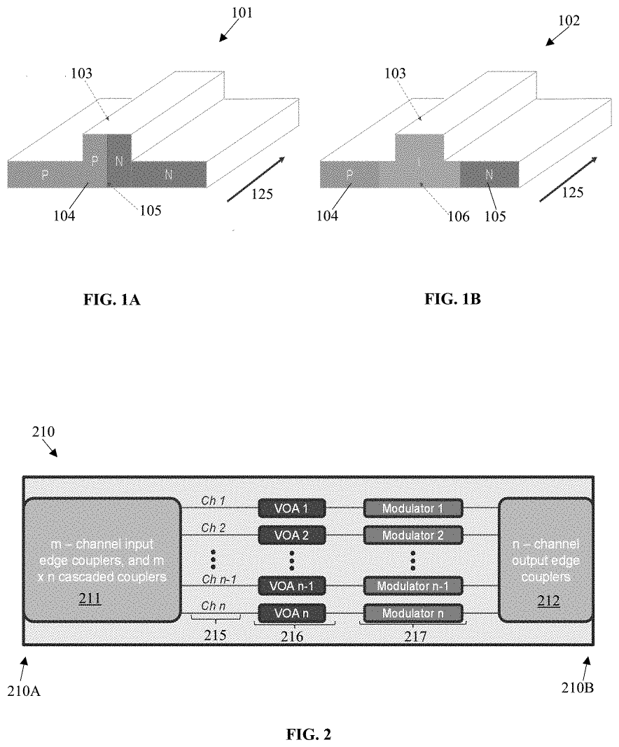

FIGS. 1A-1B are diagrams illustrating exemplary perspective views of a P-N junction 101 and a P-I-N junction 102, respectively, integrated on a silicon photonics chip, according to an aspect. As is known in the art, electrical diodes may be constructed based on a P-N junction structure, as shown in FIG. 1A, or on a P-I-N junction structure, as shown in FIG. 1B. As will be described throughout this disclosure below, silicon diodes, based on either the P-N junction 101 or the P-I-N junction 102, may be utilized as an on-chip optical alignment apparatus integrated in multi-channel silicon photonics chips, for example.

As shown in FIG. 1A, the P-N junction 101 may be formed by the joining of a P-type 104 and an N-type 105 dopants (e.g., silicon), which form a top ridge waveguide 103 in an optical modulator, for example. As an example, the P-N junction 101 shown in FIG. 1A may be integrated onto an optical channel/waveguide of a silicon photonics chip, for example, which may be silicon-based, as mentioned above. As was mentioned similarly in the Background above, the P-N junction 101 may be integrated onto a silicon waveguide/channel to form a silicon diode in an on-chip optical modulator. As shown, an optical signal 125 may be propagated through the P-N junction 101 (a silicon diode in an optical modulator, for example), such that the optical signal 125 travels through the depletion region of the P and N-type dopants 104 and 105, respectively, via the ridge waveguide 103, as an example. As will be described in greater detail when referring to FIG. 2, the exemplary P-N junction 101 may be integrated on a multi-channel integrated silicon photonics chip as a silicon diode, which may be configured as an optical modulator and adapted as a power monitoring device.

As shown in FIG. 1B, the P-I-N junction 102 may be formed by the joining of an I-type (intrinsic) region 106 (e.g., amorphous silicon) with a P-type 104 and an N-type 105 dopants (e.g., silicon), which sandwich the I-type layer 106 and form a top ridge waveguide 103 in an optical modulator or in a variable optical attenuator (VOA). As an example, the P-I-N junction 102 shown in FIG. 1B may be integrated onto an optical channel/waveguide of an integrated photonics chip, for example, which may be silicon-based, as mentioned above. As was mentioned similarly in the Background above, the P-I-N junction 102 may be integrated on a silicon waveguide/channel to form a silicon diode in an on-chip modulator or VOA. As shown, an optical signal 125 may be propagated through the P-I-N junction 102 (a silicon diode in an optical modulator or VOA, for example), such that the optical signal 125 travels through the highly charged intrinsic region 106, via the ridge waveguide 103, as an example. As will be described in greater detail when referring to FIG. 2, the exemplary P-I-N junction 102 may be integrated on a multi-channel integrated silicon photonics chip as a silicon diode, which may be provided as an optical VOA and adapted as a power monitoring device.

As mentioned previously in the Background above, the P-N junction 101 of FIG. 1A may utilize the mechanism of carrier depletion, such that electrical current is allowed to pass through the junction in a single direction (as in an electrical diode). As an example, an external voltage (not shown) may be applied to the P-N junction 101 to bias the depletion region of the ridge waveguide 103; as is known in the art, the P-N junction 101 may be forward-biased or reverse-biased. For example, when the P-N junction 101 is forward-biased, electric charge is allowed to flow freely due to reduced resistance of the depletion region. Alternatively, when the P-N junction 101 is reverse-biased, the junction barrier, and therefore the depletion region resistance, is greatly increased, such that electric charge flow is greatly reduced. Similarly, as also described in the Background above, the P-I-N junction 102 of FIG. 1B may utilize the mechanism of carrier injection, such that electric current may freely and speedily move across the intrinsic region (I-region 106), as is known. As an example, the P-I-N junction 102 may also be biased by an external voltage (not shown), such that the P-I-N junction 102 can be forward-biased or reverse-biased. When the P-I-N junction 102 is forward-biased, for example, charge carriers are transported much easier from the P (104) to the N (105) regions. On the other hand, when the P-I-N junction 102 is reverse-biased, for example, the electrical charge flow is greatly reduced. As will be described in greater detail throughout this disclosure below, biasing of the P-N and P-I-N junctions 101 and 102, respectively may enable the photocurrent, and thus the optical power, of an optical signal propagating along the ridge waveguides 103 to be electrically measured.

FIG. 2 is a diagram illustrating a top view of a multi-channel integrated silicon photonics chip 210, according to several aspects. As mentioned previously above in the Background, integrated silicon photonics chips may be used in the field of integrated photonics for optical communications applications. The multi-channel integrated silicon photonics chip (“multi-channel integrated silicon photonics chip,” “integrated silicon photonics chip,” “integrated photonics chip,” “silicon photonics chip”) 210 may be utilized as a transmitter chip, as described above, for transmitting laser light to optical communications products (e.g., optical receivers), for example. As will be described throughout this disclosure below, the integrated photonics chip 210 may be adapted to reliably measure the power of incoming optical signals, such that laser light may be easily and cost-effectively aligned and therefore optically coupled to the integrated photonics chip 210.

As shown in FIG. 2, the integrated photonics chip 210 may be provided with a first functional block 211 comprising an m-number of input edge couplers (not shown), which may be aligned to an input edge or first end 210A of the integrated photonics chip 210, and an m×n number of cascaded couplers (not shown), such as m×n splitters (e.g., 1×2 splitters, 2×2 splitters, etc.) or tunable couplers with differential thermo-optic phase shifters, for example, where m denotes the number of input ports (each having an input edge coupler) and n denotes the number of optical channels, to be described later, such that 1≤m≤n. As an example, the input edge couplers (not shown) may be adapted for receiving and coupling optical light into the integrated photonics chip 210 for transmitting of the coupled optical light, as needed. As shown, a plurality of optical channels 215, where a total number of channels is n, with at least one channel being the minimum (e.g., n≥1), for example, may be parallelly disposed on and extend a length of the integrated photonics chip 210. The optical channels 215 may be optically branched from the m×n cascaded couplers (not shown) contained within the first functional block 211, for example. As mentioned previously above, the integrated photonics chip 210 may further comprise a plurality of VOAs 216 and a plurality of modulators 217, as shown as an example. As shown, each optical channel 215 may be optically provided with a VOA 216 followed by a modulator 217, such that, for example, optical channel Ch 1 comprises the VOA at VOA 1 followed by the modulator at Modulator 1, as shown. Finally, as shown in FIG. 2, the silicon photonics chip 210 may be provided with a second functional block 212 comprising an n-number of output ports (e.g., edge couplers) (not shown), which may be aligned to an output edge or second end 210B of the silicon photonics chip 210. Each optical channel 215 may be provided with an output port (not shown) for coupling optical light out of the integrated photonics chip 210, as an example.

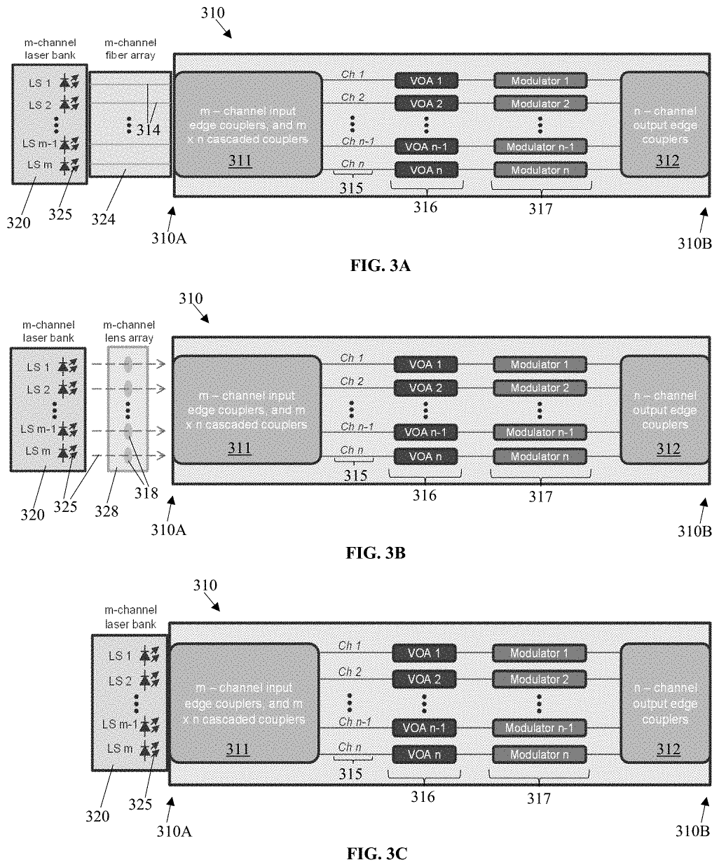

As discussed previously above, each optical channel 215 may comprise a VOA 216 and an optical modulator 217, as shown. As described previously in the Background, integrated photonics chips traditionally include VOAs, based on electrical diodes, for optical power attenuation and channel shutoff capabilities. Additionally, integrated photonics chips traditionally include optical modulators, based on electrical diodes, for example, for supporting high data rates of electro-optical conversion. The VOAs 216 shown in FIG. 2 may be constructed using the P-I-N junction (102) of FIG. 1B, discussed previously above, and the modulators 217 may be constructed using the P-N junction (101) of FIG. 1A, as an example. As described previously above when referring to FIGS. 1A-B, the P-N and P-I-N junctions may be biased by an external voltage, which will thus affect VOA and modulator functionality in this case. As will be described in greater detail when referring to FIGS. 3A-3C below, the P-N and P-I-N junctions of the optical modulators and the VOAs, respectively, may be reverse-biased, such that the optical modulators 217 and the VOAs 216 are adapted to absorb optical light, such that to electrically measure optical power of propagating laser light, for example.

FIGS. 3A-3C are diagrams illustrating top views of methods of optically aligning a laser light source 320 to the multi-channel integrated silicon photonics chip 210 of FIG. 2, according to several aspects. As mentioned above when referring to FIG. 2, the disclosed integrated silicon photonics chip 310 may be optically coupled with a laser light source for the transmission of laser light, and therefore optical power, via the integrated photonics chip 310, for example. Again, as shown in FIGS. 3A-3C, the silicon photonics chip 310 may be provided with a first and a second functional blocks 311 and 312 disposed at the input and output edges 310A and 310B, respectively, of the silicon photonics chip 310. The input edge couplers (not shown) and the cascaded couplers (not shown) contained within the first functional block 311 may optically connect to the plurality of optical channels 315, each channel having a VOA 316 and a modulator 317, as shown. Each optical channel 315 may conclude with an output edge coupler (not shown) contained within the second functional block 312, for coupling laser light out of the silicon photonics chip 310, as an example. In order to effectively and continuously transmit laser light, the silicon photonics chip 310 must be optimally aligned and optically coupled to the laser light source. As will be described in detail below, the on-chip VOAs 316 and modulators 317 may enable the silicon photonics chip 310 to be easily and effectively coupled to the laser light source, such that laser light, and therefore optical power, may subsequently be transmitted via the silicon photonics chip 310.

FIG. 3A is a diagram illustrating a top view of a first method of optically aligning a laser bank 320 to the silicon photonics chip 310 via a fiber array 324, according to an aspect. As mentioned above, the silicon photonics chip 310 must be well-aligned to the laser light source, such that an optimal amount of optical power can be transmitted via the silicon photonics chip 310 (i.e., a maximal amount of the laser light being transmitted). As shown in FIG. 3A, a first approach to optically aligning the laser light source to the silicon photonics chip 310 may include a fiber array 324, for example. As shown, the laser light source may be a laser bank 320 (e.g., a laser chip), which may contain a plurality of laser diodes LS 1-LS m, as an example, where m is the number of input ports of the silicon photonics chip 310. Each laser diode of the laser bank 320 may emit laser light 325 for the transmission of optical power, as similarly mentioned above. The laser diodes within the laser bank 320 may emit laser light having the same wavelengths or different wavelengths, as needed, for example. The laser bank 320 may be optically aligned to the fiber array 324, as shown, which may comprise a plurality of fiber channels 314, for example. It should be understood that the illustrated number of fiber channels 314 is exemplary, and as many or as few fiber channels may be provided, as needed. Finally, as shown, the fiber array 324 may be optically aligned to the input edge 310A of the integrated photonics chip 310, such that each functional fiber channel 314 aligns with an input edge coupler (not shown) at the input edge 310A.

As described previously in the Background above, on-chip SiGe photodiodes, optically connected to optical channels via tap couplers having high tap ratios, for example, are conventionally used to electrically measure and therefore monitor the power of the incoming laser light, such that physical adjustments may be made while aligning the laser light source to the photonics chip. As shown in FIG. 3A, no SiGe photodiodes or tap couplers are present on the integrated photonics chip 310. Thus, in order to monitor the optical power being coupled into the silicon photonics chip 310 during the laser alignment process, the electrical diodes residing within the waveguide of the integrated silicon modulators 317 and/or the photodiodes of the VOAs 316 can be reversely biased, as mentioned previously above. As described previously above when referring to FIGS. 1A-1B, a biasing voltage can be applied to the P and the N regions of each of the P-N and P-I-N junctions to reversely bias the junctions. As an example, depletion mode silicon modulators based on P-N junctions usually contain defects formed as a result of the implantation of the P- and the N-type dopants, and these defects may actually be beneficial under reverse-bias for assisting in light absorption (i.e., photon absorption), and thus the electrical measurement of optical power, at wavelengths longer than silicon's direct and indirect band gap (e.g., 1.11 eV). Similarly, the defects present in P-I-N junctions of a photodetector-based VOA can induce photoconductance effects under reverse-bias, which may thus enhance the photodetection (light absorption) of the optical light, and thus the electrical measurement of photocurrent.

Referring back to FIG. 3A, it should be understood that only the modulator 317 or the VOA 316, not both, are needed to be reversely biased on any particular optical channel 315 to achieve the above-described optical power-monitoring functionality. Furthermore, it is not necessary for the silicon diodes (of the modulators 317 and/or the VOAs 316) to be reversely biased on every optical channel 315. As an example, in some cases, only the silicon diodes (e.g., formed by P-N and/or P-I-N junctions) of the modulators 317 or the VOAs 316 disposed on the first channel (Ch 1) and on the last channel (Ch n) need to be used as power monitors during the laser alignment process, such that either VOA 1 or Modulator 1 is reverse biased and either VOA n or Modulator n is reverse biased, for example. It should be understood that the pluralities of VOAs 316 and modulators 317 may each be provided with electrical contact means integrated on the chip for receiving a voltage, such that to bias the silicon diodes within the VOAs and the modulators. As such, for example, the photon energy of the optical signal collected by the reverse-biased VOA 316 and/or modulator 317 may be converted into an electrical signal/current (as in a conventional photodetector), which may be read by an external computer, as an example. It should also be understood that the biasing voltages on the silicon diodes may be applied manually by a user or autonomously by a computer having a control algorithm, for example. It should also be understood that, while a laser bank 320 is illustrated as being the laser light source, other types of laser light sources may be used, such as a single laser, for example. It should be noted that the respective modulators 317 and/or VOAs 316 may receive the same biasing voltage or different biasing voltages, as will be described in more detail later.

Thus, an advantage of using silicon-based modulators and VOAs is that the use of additional on-chip tap couplers bundled with photodiodes may be negated, which simplifies the design of the disclosed silicon photonics chip, and thus reduces manufacturing costs. Another advantage is that, because the use of additional on-chip tap couplers bundled with photodiodes may be negated, the overall size of the integrated photonics chip may be miniaturized, further reducing manufacturing costs. An additional advantage is that, because no electrical power is needed for operating the negated on-chip photodiodes, the operational costs associated with operating the disclosed integrated photonics chip may be reduced. Another advantage is that, because no tap couplers are used, the wavelength dispersion of the propagating laser light may be improved. Another advantage is that, because no SiGe photodetectors are used on the integrated photonics chip, the typical issues of high ESD and specificity of the SiGe epitaxial growth yield can be avoided.

As described above, the on-chip modulators 317 and VOAs 316 may be adapted to function as power monitors (by reversely biasing their respective silicon diodes) for optimizing the laser alignment process. As shown in FIG. 3A, as an example, once the laser bank 320 and the fiber array 324 are initially abutted and aligned to the input edge 310A of the integrated photonics chip 310, the laser diodes LS 1-LS m may be actuated, such that laser light 325 is propagated through the fiber channels 314 and into the optical channels 315, for example. As the laser light beams propagate along the optical channels 315, the selectively reverse-biased VOAs 316 and/or modulators 317 acting as power monitors may continuously measure and monitor the light intensity of travelling light signals, which may be output as user-feedback to an external computer for subsequent electrical measurement of the corresponding optical power, for example. Using these power measurements, the physical placements, and alignments, of the laser bank 320, the fiber array 324, and/or the silicon photonics chip 310 may be adjusted until a maximal amount of laser light, and therefore optical power, is transmitted completely through the silicon photonics chip, for example. After the laser bank 320 is aligned, the modulators 317 and/or the VOAs 316 that were selected for power monitoring will continue to function normally as originally designed, that is, the modulators 317 will work normally under a reverse-bias for high-speed electro-optical conversion, and the VOAs 316 will work normally under a forward bias for optical power attenuation or channel shutoff, as needed. Thus, in other words, the same optical component (e.g., modulator or VOA) can be used for both laser alignment and product operation under its proper biasing condition. Thus, an advantage is that the required number of on-chip optical components is simplified and thus reduced, increasing chip optimization and circuit miniaturization.

FIG. 3B is a diagram illustrating a top view of a second method of optically aligning a laser bank 320 to the silicon photonics chip 310 via a lens array 328, according to an aspect. As shown in FIG. 3B, a second approach to optically aligning the laser light source to the silicon photonics chip 310 may include a lens array 328, for example. As shown, the laser light source may still be the laser bank 320 (e.g., a laser chip), which may contain a plurality of laser diodes LS 1-LS m, as an example, where m is the number of input ports of the silicon photonics chip 310. As described above, each laser diode of the laser bank 320 may emit laser light 325 for the transmission of optical power. The laser diodes within the laser bank 320 may emit laser light having the same wavelengths or different wavelengths, as needed, for example. The laser bank 320 may be optically aligned to the lens array 328, as shown, which may comprise a plurality of lenses 318, for example. It should be understood that the illustrated number of lenses 318 is exemplary, and as many or as few lenses may be provided, as needed. Finally, as shown, the lens array 328 may be optically aligned to the input edge 310A of the integrated photonics chip 310, such that each functional lens 318 axially aligns with an input edge coupler (not shown) at the input edge 310A.

As previously described above, the laser bank 320 may be adapted to transmit laser light 325, and therefore optical power, to an external optical device (e.g., receiver or fiber array) disposed at or near the output edge 310B of the silicon photonics die 310. As previously discussed above when referring to FIG. 3A, the on-chip VOAs 316 and/or the optical modulators 317 may be configured as power monitors by reversely biasing their respective silicon diodes (applying a biasing voltage to their respective P-N and/or P-I-N junctions). As such, in this second approach, photocurrent of the laser light 325 coupled into the integrated photonics chip 310 via the lens array 328 may be continuously electrically measured using the reverse-biased on-chip VOAs 316 and/or optical modulators 317, such that the resultant optical power of the propagating laser light 325 may be monitored, for example. As similarly described above, the laser light 325 may be coupled into the lens array 318, such that each laser beam travels through a lens 318, which directs the laser beam into the input edge couplers (not shown) disposed at the input end 310A of the integrated photonics chip 310. As the laser light 325 propagates through the input edge couplers and the cascaded couplers (not shown), the laser light may be directed onto the plurality of optical channels 315. As discussed above, as the optical signals 325 propagate along the optical channels 315, the reverse-biased VOAs 316 and/or modulators 317 may electrically measure the photocurrent of each optical signal (or at least two optical signals), such that the optical power calculated using the measured photocurrent may be utilized by a user or a computer, for example.

As similarly described above, using the optical power measurements calculated from the photocurrents detected by the VOAs 316 and/or the modulators 317, the laser bank 320, the lens array 328, and/or the integrated photonics chip 310 may be adjusted and/or repositioned, such that a greater amount of laser light 325 may enter the photonics chip, for example. Knowing the power rating of the laser source (e.g., the input power), and having a set output power goal in mind (sufficiently close to the input power or a fraction thereof, for example), a maximal power output value can be established to be used as a goal for determining when optimal laser alignment is achieved, for example. The relative positions of each of the laser bank 320, the lens array 328, and/or the silicon photonics chip 310 may be adjusted until a maximal amount of laser light 325 is transmitted by the silicon photonics chip 310, determined by the power measurement calculated using the reverse-biased VOAs 316 and/or modulators 317, as discussed above. As such, the laser light source (laser bank 320) may be optically aligned to the silicon photonics die 310 for the optimal transmission of optical power via the laser light 325 when the VOAs 316 and/or modulators 317 read out a photocurrent corresponding to the predetermined power output goal. It should be understood that the physical adjusting of the lens bank 320, the lens array 328, and/or the silicon photonics die 310 may be done manually (by a user) or automatically (by a computer using a control algorithm) using the calculated power measurements.

FIG. 3C is a diagram illustrating a top view of a third method of optically aligning a laser bank 320 directly attached to the silicon photonics chip 310, according to an aspect. As discussed above, FIGS. 3A and 3B depict exemplary approaches of aligning a laser bank 320 to the silicon photonics chip 310 using external optical devices, such as a fiber array 324 and a lens array 328, as examples. It should be understood that other optical means, such as a waveguide array disposed on a planar light wave circuit, may be used as intermediaries to help couple laser light to the silicon photonics die. As a third approach, the laser bank 320 may be attached directly to the input edge 310A of the silicon photonics die 310, such that laser light 325 may be directly coupled to the silicon photonics die 310, as an example.

As similarly discussed above, laser light 325 emitted from laser diodes LS 1 LS m contained within the laser bank 320 may be launched into the input edge couplers (not shown) disposed along the input edge 310A of the integrated photonics chip 310, for example. The laser light 325 may subsequently be split by the cascaded couplers (not shown), for example, and may propagate along the plurality of optical channels 315, as an example. As described above, the VOAs 316 and/or the modulators 317 may be reverse-biased, such that their respective silicon diodes are adapted to absorb light and thus electrically measure the photocurrent of each propagating laser beam, for example. As the laser light beams 325 propagate along the optical channels 315, the selectively reverse-biased VOAs 316 and/or modulators 317 may measure and read out, as discussed above, the photocurrent of each of the laser light beams (or at least two laser light beams), which may be laser light beams), which may be converted into optical power (via calculation, for example). Again, as described previously above, the optical power of only two laser light beams need to be continuously monitored, in certain applications, for the laser alignment process to be effectively completed. The propagating laser light beams may then be coupled out of the integrated photonics chip 310 via the output edge couplers (not shown) for the transmission of optical power, as described previously above.

As similarly described above, using the optical power measurements outputted (indirectly) from the reverse-biased VOAs 316 and/or modulators 317, the laser bank 320 and/or the integrated photonics chip 310 may be adjusted and/or repositioned, as needed, such that a greater amount of laser light 325 enters the photonics chip, for example. Knowing the power rating of the laser light source (e.g., the input power), and having a set output power goal in mind (sufficiently close to the input power or a fraction thereof, for example), a maximal power output value can be established to be used as a goal for determining when optimal laser alignment is achieved, as an example. The relative positions of each of the laser bank 320 and/or the silicon photonics chip 310 may be adjusted until a maximal amount of laser light 325 is transmitted by the silicon photonics chip 310, determined by the optical power measurement received (indirectly) from the reverse-biased VOAs 316 and/or modulators 317, as discussed above. As such, the laser source (laser bank 320) may be optically aligned to the silicon photonics die 310 for the optimal transmission of optical power via the laser light 325 when the VOAs 316 and/or modulators 317 read out the predetermined power output goal. The laser bank 320 may then be directly attached and secured to the input edge 310A, as shown in FIG. 3C, for the continuous transmission of optical power, as an example.

Thus, as outlined herein above, the disclosed reverse-biased VOAs 316 and modulators 317 may effectively and efficiently function as a power monitoring system (effectively as photodetectors) adapted to electrically measure the photocurrent, and thus the optical power, of laser light 325 being propagated along the integrated photonics die 310. As shown in FIGS. 3A-3C, the reverse-biased VOAs 316 and modulators 317 may thus support each of the exemplary approaches outlined above and may support numerous other approaches not explicitly shown or described herein. Thus, an advantage of the disclosed optical alignment method using reverse-biased VOAs and modulators is that a laser source may be efficiently and cost-effectively aligned to an integrated photonics die. Another advantage of the disclosed optical alignment method is that a laser source may be aligned to an integrated photonics die using existing, on-chip optical components, thus reducing operational costs. It should be understood that, throughout the description above, for the laser alignment process, for example, a primary computer or device/instrument may be adapted to autonomously calculate (or convert to) the optical power using the detected photocurrents, and a second computer or device may implement the necessary alignment adjustments, as discussed above.

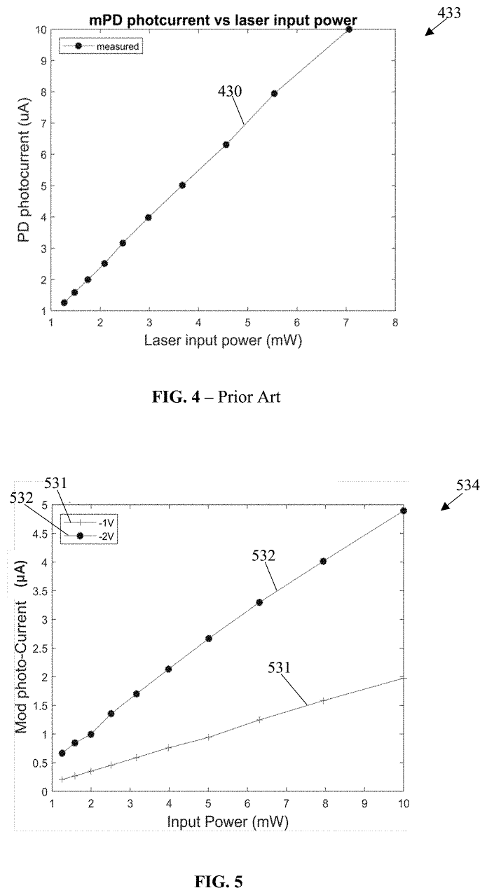

FIG. 4 is an exemplary plot 433 illustrating the photocurrent measured via the prior art approach of using a SiGe photodiode, according to an aspect. As described previously in the Background above, SiGe photodiodes are conventionally used as on-chip power monitors by measuring the photocurrent of the laser light, and therefore, the optical power. Optically connected to the optical channels (e.g., 315 in FIGS. 3A-3C) via tap couplers having certain tap ratios, the SiGe photodiodes are adapted to continuously detect laser light, such that to electrically measure and output the photocurrent of the laser light for providing feedback regarding the position of the laser source and angle of incidence of the laser beam, and thus what physical adjustments are necessary for aligning the laser source, as described previously in the Background above.

As shown by the experimental results captured in the plot 433 of FIG. 4, the tapped SiGe photodetector may electrically read photocurrents in microamperes (pA) as a function of the input laser source power in milliwatts (mW). As expected, as the input power of the incoming laser light is increased, as indicated on the x-axis of the plot 433, the measured photocurrent also increases, as indicated on the y-axis. As shown by the photocurrent measurement, represented by curve 430, SiGe photodetectors may function as effective power monitors for aiding in the laser alignment process, for example. However, as explained in the Background above, SiGe photodetectors possess low ESD voltage ratings, increasing their handling sensitivity and thus their susceptibility to decreases in epitaxial yield. As will be described in detail below, the above-described reverse-biased VOAs (e.g., 316) and modulators (e.g., 317) may each produce a photocurrent measurement curve similar to that shown by 430 in FIG. 4, thus illustrating the effectiveness of the reverse-biased VOA and modulator as a power monitoring system.

FIG. 5 is an exemplary plot 534 illustrating the photocurrent measured via a modulator as a function of laser light source power, according to an aspect. As described throughout this disclosure above, the on-chip modulators, shown by 317 in FIGS. 3A-3C, for example, may be selectively adapted as power monitors by reversely biasing their respective P-N junction-based (or in some cases, P-I-N junction-based) silicon diodes. As will be described in detail below, the reverse-biased on chip modulator disclosed herein may function as an effective power monitor comparable to the SiGe photodiode described above when referring to FIG. 4, for example.

As shown in FIG. 5, the plot 534 illustrates experimental results of using a pigtail P-N junction-based modulator integrated on an optical channel of an integrated photonics chip. As described previously above when referring to FIGS. 3A-3C, laser light coupled into the integrated photonics chip may propagate along the optical channel, and may optically contact the modulator, which is configured as a power monitor for aligning a laser source to the integrated photonics chip. The plot 534 of FIG. 5 thus illustrates the photocurrent (on the y-axis) in microamperes measured from the reverse-biased modulator, when the laser is optically aligned to the integrated photonics chip, as a function of laser source power (on the x-axis) in milliwatts. As shown, the P-N junction diode of the modulator being tested may be reverse-biased at −1 volt (V), shown at 531, and at −2V, shown at 532, for example. For both of the biasing voltages −1V and −2V, the resultantly measured photocurrents, shown by the curves 531, 532, respectively, on the plot 534, increase as the input power increases. As an example, the dark current of the reverse-biased modulator may be as low as 7 nanoamperes (nA) under a reverse-bias of −2V, which is lower than that of SiGe photodiodes, rendering the modulator with a much higher signal-to-noise ratio, which is desirable/preferable for optimal performance.

As illustrated by the plot 534 of FIG. 5, the photocurrents measured by the modulator under reverse-biases of −1V and −2V, at 531 and 532, respectively, are directly proportional to the input laser power, as an example. In comparison with the plot 433 of FIG. 4 of the photocurrent measured by the prior art tapped SiGe photodiode, it can clearly be seen that the detected photocurrents of the reverse-biased modulator are very similar in scale and fall along an almost identical power range. For example, referring to FIG. 5, the measured photocurrents range from about 0.5 μA up to about 5 μA under a −2V reverse-bias, while the measured photocurrents range from about 0.3 μA up to about 2 μA under a −1V reverse-bias, as shown. In comparison with the measured photocurrents shown previously in FIG. 4, for example, which range from about 1 μA up to about 10 μA, the detected photocurrents (along curves 531 and 532) are quite comparable, particularly for the modulator under a −2V reverse-bias, for example. As another example, silicon-based modulators typically possess a Human Body Model (HBM) ESD rating of at least 500V, which is much higher than that of the SiGe photodiode, as described previously above when referring to FIG. 4. Thus, the silicon-based modulator possesses a much lower handling sensitivity, thus relaxing the handling requirement regarding the ESD rating of the integrated photonics chip handling fabrication and packaging house, for example. Therefore, because of the reduction in handling sensitivity, the overall epitaxial growth yield is improved, which is particularly advantageous for multi-channel devices, as an example.

Additionally, as shown in FIG. 5, the measured photocurrent curves 531 and 532 span a range of input power from about 1 mW up to 10 mW, and presumably onward, as an example. As shown previously in FIG. 4, the measured photocurrent curve 430 spans an overlapping range of input power, from about 1 mW up to 7 mW, and presumably onward, as an example. Thus, as stated previously above when referring to FIGS. 3A-3C, the reverse-biased silicon-based modulator disclosed herein possesses equivalent power-monitoring performance to the conventional tapped SiGe photodiode and may thus be a superior power-monitoring tool due to its various additional benefits described throughout this disclosure above. It should be understood that the reverse-biasing voltage applied to the modulator may be particularly chosen to accommodate the expected input power of the laser source being aligned to the integrated photonics chip, such that the reverse-biased modulator can detect the photocurrent of the optical signal within a range of input powers, as shown in FIG. 5, for example.

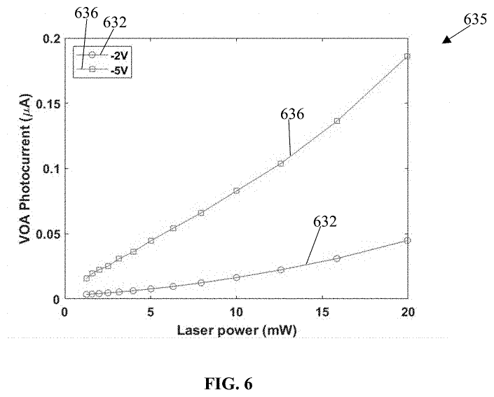

FIG. 6 is an exemplary plot 635 illustrating the photocurrent measured via a VOA as a function of laser light source power, according to an aspect. As described throughout this disclosure above, the on-chip VOAs, shown by 316 in FIGS. 3A-3C, for example, may be selectively adapted as power monitors by reversely biasing their respective P-I-N junction-based silicon diodes. As will be described in detail below, the reverse-biased on chip VOA disclosed herein may function as an effective power monitor comparable to the SiGe photodiode described previously above when referring to FIG. 4, for example.

As shown in FIG. 6 as an example, the plot 635 illustrates experimental results reflecting the use of a reverse-biased P-I-N junction-based VOA integrated on an optical channel of an integrated photonics chip. As described previously above when referring to FIGS. 3A-3C, laser light coupled into the integrated photonics chip may propagate along the optical channel, and may optically contact the VOA, which is configured as a power monitor for aligning a laser source to the integrated photonics chip. The plot 635 of FIG. 6 thus illustrates the photocurrent (on the y-axis) in microamperes measured from the VOA, when the laser is optically aligned to the integrated photonics chip, as a function of laser source power (on the x-axis) in milliwatts. As shown, the P-I-N junction diode of the VOA being tested may be reverse-biased at −2V volts (V), shown at 632, and at −5V, shown at 636, for example. For both of the biasing voltages −2V and −5V, the resultantly measured photocurrents, shown by the curves 632 and 636, respectively, on the plot 635, increase as the input power increases. As an example, the dark current of the reverse-biased VOA may be as low as 10 nA under a reverse-bias of −5V, which is lower than that of SiGe photodiodes, rendering the VOA with a much higher signal-to-noise ratio, which is desirable/preferable for optimal performance.

As illustrated by the plot 635 of FIG. 6, the photocurrents measured by the VOA under reverse-biases of −2V and −5V, at 632 and 636, respectively, increase as the input laser power increases, as an example. In comparison with the plot 433 of FIG. 4 of the photocurrent measured by the prior art SiGe photodiode, it can clearly be seen that the detected photocurrents of the reverse-biased VOA are very similar in proportionality and fall along an almost identical power range. For example, referring to FIG. 6, the measured photocurrents range from about 0.01 μA up to about 0.2 μA under a −5V reverse-bias, while the measured photocurrents range from about 0.005 μA up to about 0.05 μA under a −2V reverse-bias, as shown. In comparison with the measured photocurrents shown previously in FIG. 4, for example, which range from about 1 μA up to about 10 μA, the detected photocurrents (along curves 632 and 636) are comparable in terms of overall proportionality and shape, especially for the VOA under a −5V reverse-bias, for example. While the detected photocurrents of the VOA may appear weaker overall, due to the much lower photocurrent values of the y-axis, for example, the actual power reaching the VOA is lower, due to the high grating coupler loss at the input during the experiment, for example, which may thus accommodate for the lowered photocurrent spectrum shown in FIG. 6. Moreover, although the photocurrent measured by the VOA is smaller, the signal-to-noise ratio is high, as mentioned above, due to the very low dark current, so using the reverse-biased VOA as an on-chip power monitor is still very feasible.

Additionally, as shown in FIG. 6, the measured photocurrent curves 632 and 636 span a range of input power from about 1 mW up to 20 mW, and presumably onward, as an example. As shown previously in FIG. 4, the measured photocurrent curve 430 spans an overlapping range of input power, from about 1 mW up to 7 mW, and presumably onward, as an example. Thus, as shown in FIG. 6, the disclosed VOA may stably measure photocurrents across a wide range of input laser powers. Therefore, as stated previously above when referring to FIGS. 3A-3C, the reverse-biased silicon-based VOA disclosed herein possesses equivalent power-monitoring performance to the prior art tapped SiGe photodiode and may thus be a superior power-monitoring device due to its various additional benefits described throughout this disclosure above. It should be understood that the reverse-biasing voltage applied to the VOA may be particularly chosen to accommodate the expected input power of the laser source being aligned to the integrated photonics chip, such that the reverse-biased VOA can detect the photocurrent of the optical signal within a range of input powers, as shown in FIG. 6, for example.

It should be understood that, if more than one modulator and/or VOA on any given integrated photonics chip is to receive a biasing voltage, such that to configure the modulators and/or VOAs as power monitors, each modulator and/or VOA may receive the same biasing voltage or different biasing voltages, as needed, as an example. It should be understood that the disclosed laser alignment system and method may be applied to integrated photonics devices based on various platforms, such as, for example, silicon (as disclosed herein above), silicon nitride, silica, lithium niobate, polymer, III-V materials, hybrid integrated platforms, etc. It should also be understood that the modulators and the VOAs disclosed herein can be realized using various suitable structures, such as, for example, Mach-Zehnder Interferometers, ring resonators, photonic crystals, Bragg gratings, and the like. It should also be understood that the disclosed method may align laser light propagating at multiple wavelengths, such as, for example, the visible light spectrum, O, E, S, C, or L-band. The potential applications of the disclosed invention may be not only be applied to optical communications, but may also be applied to optical sensing, optical computing, automotive applications, quantum applications, etc.

It may be advantageous to set forth definitions of certain words and phrases used in this patent document. The term “couple” and its derivatives refer to any direct or indirect communication between two or more elements, whether or not those elements are in physical contact with one another. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

Further, as used in this application, “plurality” means two or more. A “set” of items may include one or more of such items. Whether in the written description or the claims, the terms “comprising,” “including,” “carrying,” “having,” “containing,” “involving,” and the like are to be understood to be open-ended, i.e., to mean including but not limited to. Only the transitional phrases “consisting of” and “consisting essentially of,” respectively, are closed or semi-closed transitional phrases with respect to claims.

If present, use of ordinal terms such as “first,” “second,” “third,” etc., in the claims to modify a claim element does not by itself connote any priority, precedence or order of one claim element over another or the temporal order in which acts of a method are performed. These terms are used merely as labels to distinguish one claim element having a certain name from another element having a same name (but for use of the ordinal term) to distinguish the claim elements. As used in this application, “and/or” means that the listed items are alternatives, but the alternatives also include any combination of the listed items.

As used throughout this application above, the phrases “laser light,” “laser light beam,” “light beam,” “laser signal,” “optical signal,” and the like are interchangeable. Each of the aforementioned phrases and/or terms are intended to refer generally to forms of light, and more specifically, electromagnetic radiation used in the fields of optics and integrated photonics. As also used herein, the term “power” is to be interpreted as the power, in milliwatts, for example, of the laser signals being transmitted via the transmitter chip. Thus, if reference is made to the power of a particular optical channel or output port, it is to be understood as meaning the power of the laser signal travelling through said particular optical channel or output port, for example, calculated using the laser signal's measured photocurrent. Additionally, the phrase “optically couple” and its equivalents, as used herein, is to be understood as meaning “traverse” or “cause to travel” in reference to optical light signals.

Throughout this description, the aspects, embodiments or examples shown should be considered as exemplars, rather than limitations on the apparatus or procedures disclosed or claimed. Although some of the examples may involve specific combinations of method acts or system elements, it should be understood that those acts and those elements may be combined in other ways to accomplish the same objectives.

Acts, elements and features discussed only in connection with one aspect, embodiment or example are not intended to be excluded from a similar role(s) in other aspects, embodiments or examples.

Aspects, embodiments or examples of the invention may be described as processes, which are usually depicted using a flowchart, a flow diagram, a structure diagram, or a block diagram. Although a flowchart may depict the operations as a sequential process, many of the operations can be performed in parallel or concurrently. In addition, the order of the operations may be re-arranged. With regard to flowcharts, it should be understood that additional and fewer steps may be taken, and the steps as shown may be combined or further refined to achieve the described methods.

If means-plus-function limitations are recited in the claims, the means are not intended to be limited to the means disclosed in this application for performing the recited function, but are intended to cover in scope any equivalent means, known now or later developed, for performing the recited function.

Claim limitations should be construed as means-plus-function limitations only if the claim recites the term “means” in association with a recited function.

If any presented, the claims directed to a method and/or process should not be limited to the performance of their steps in the order written, and one skilled in the art can readily appreciate that the sequences may be varied and still remain within the spirit and scope of the present invention.

Although aspects, embodiments and/or examples have been illustrated and described herein, someone of ordinary skills in the art will easily detect alternate of the same and/or equivalent variations, which may be capable of achieving the same results, and which may be substituted for the aspects, embodiments and/or examples illustrated and described herein, without departing from the scope of the invention. Therefore, the scope of this application is intended to cover such alternate aspects, embodiments and/or examples. Hence, the scope of the invention is defined by the accompanying claims and their equivalents. Further, each and every claim is incorporated as further disclosure into the specification.

What is claimed is:

1. An integrated photonics chip comprising:
a plurality of optical channels extending a length of the integrated photonics chip;
at least one variable optical attenuator (VOA) being optically connected to one of the plurality of optical channels, the at least one VOA comprising a silicon diode;
at least one modulator being optically connected to another of the plurality of optical channels, the at least one modulator comprising a silicon diode;
wherein the silicon diodes of the at least one VOA and the at least one modulator are adapted to receive biasing voltages; and
wherein an application of the biasing voltages causes the silicon diodes of the at least one VOA and the at least one modulator to be reverse-biased, such that the at least one VOA is adapted to detect a photocurrent of a first optical signal being propagated along the one of the plurality of optical channels, and the at least one modulator is adapted to detect a photocurrent of a second optical signal being propagated along the another of the plurality of optical channels.

2. The integrated photonics chip of claim 1, further comprising:
a first and a second input ports disposed at and aligned to a first end of the integrated photonics chip, the first and the second input ports being adapted to receive the first and the second optical signals, respectively; and
at least one cascaded coupler optically connected to the first and the second input ports;
wherein a first and a second optical channels of the plurality of optical channels are each branched from one of the at least one cascaded couplers.

3. The integrated photonics chip of claim 2, further comprising a first and a second output ports disposed at a second end of the integrated photonics chip, the first and the second output ports being optically connected to the first and the second optical channels, respectively, and being adapted to couple the first and the second optical signals, respectively, out of the second end.

4. The integrated photonics chip of claim 1, wherein the silicon diode of the at least one VOA is P-I-N junction-based.

5. The integrated photonics chip of claim 1, wherein the silicon diode of the at least one modulator is P-N junction-based.

6. The integrated photonics chip of claim 1, wherein the silicon diode of the at least one modulator is P-I-N junction-based.

7. The integrated photonics chip of claim 2, wherein the first and the second optical signals are launched into the first and the second input ports, respectively, via a laser light source.

8. The integrated photonics chip of claim 1, wherein the biasing voltages are equal in value.

9. The integrated photonics chip of claim 2, wherein the first and the second input ports are edge couplers.

10. A method of optically aligning a laser light source to an integrated photonics chip, the integrated photonics chip comprising a first and a second optical channels, and a first and a second variable optical attenuators (VOAs) being optically connected to the first and the second optical channels, respectively, the first and the second VOAs each having a silicon diode, wherein the silicon diodes of the first VOA and the second VOA are each adapted to receive a first and a second biasing voltages, respectively, the method comprising the steps of:
positioning the laser source to face a first end of the integrated photonics chip, such that an optical signal being launched by the laser source can enter the integrated photonics chip at the first end;
applying the first and the second biasing voltages to each of the silicon diodes of the first and the second VOAs, the first and the second biasing voltages causing the silicon diodes to become reverse-biased, such that a photocurrent of a propagating optical signal can be detected by each of the first and the second VOAs;
operating the laser source, such that a first and a second optical signals are launched into the first and the second optical channels, respectively, at the first end; and
measuring an optical power of each of the first and the second optical signals by detecting the photocurrent of each of the first and the second optical signals, respectively, using the reverse-biased first and second VOAs, such that to monitor and thus selectively adjust a position of the laser source and an angle of incidence of each of the first and the second optical signals for optically aligning the laser source to the integrated photonics chip.

11. The method of claim 10, wherein the integrated photonics chip further comprises a first and a second input ports disposed at the first end of the integrated photonics chip and being optically connected to the first and the second optical channels, respectively, the first and the second input ports being adapted to receive the first and the second optical signals, respectively.

12. The method of claim 10, wherein the laser source is a laser chip having a first and a second laser diodes adapted to produce the first and the second optical signals, respectively.

13. The method of claim 11, wherein the first and the second optical signals are launched into the integrated photonics chip via a fiber array optically aligned to the first end, the fiber array having a first and a second fiber channels being optically aligned to the first and the second input ports, respectively.

14. The method of claim 11, wherein the first and the second optical signals are launched into the integrated photonics chip via a lens array optically aligned to the first end, the lens array having a first and a second lenses being optically aligned to the first and the second input ports, respectively.

15. The method of claim 10, wherein the applied first and second biasing voltages are in a range between −5 Volts and −2 Volts.

16. A method of optically aligning a laser light source to an integrated photonics chip, the integrated photonics chip comprising a first and a second optical channels, and a first and a second modulators being optically connected to the first and the second optical channels, respectively, the first and the second modulators each having a silicon diode, wherein the silicon diodes of the first and the second modulators are each adapted to receive a first and a second biasing voltages, respectively, the method comprising the steps of:
positioning the laser source to face a first end of the integrated photonics chip, such that an optical signal being launched by the laser source can enter the integrated photonics chip at the first end;
applying the first and the second biasing voltages to each of the silicon diodes of the first and the second modulators, respectively, the first and the second biasing voltages causing the silicon diodes to become reverse-biased, such that a photocurrent of a propagating optical signal can be detected by each of the first and the second modulators;
operating the laser source, such that a first and a second optical signals are launched into the first and the second optical channels, respectively, at the first end; and
measuring an optical power of each of the first and the second optical signals by detecting a photocurrent of each of the first and the second optical signals, respectively, using the reverse-biased first and second modulators, such that to monitor and thus selectively adjust a position of the laser source and an angle of incidence of each of the first and the second optical signals for optically aligning the laser source to the integrated photonics chip.

17. The method of claim 16, wherein the laser source is a laser chip having a first and a second laser diodes adapted to produce the first and the second optical signals, respectively.

18. The method of claim 16, wherein the silicon diodes of the first and the second modulators are P-N junction-based.

19. The method of claim 16, wherein the integrated photonics chip further comprises:
a first and a second variable optical attenuators (VOAs) each being optically connected to the first and the second optical channels, respectively, the first and the second VOAs each having a silicon diode;
wherein the silicon diodes of the first and the second VOAs are P-I-N junction-based.

20. The method of claim 16, wherein the applied first and second biasing voltages are in a range between −5 Volts and −1 Volts.
